(19) United States
(12) Patent Application Publication
(10) Pub. No.: US 2025/0176238 A1
(43) Pub. Date: May 29, 2025

(54) METHOD FOR MAKING A DEEP TRENCH ISOLATION BETWEEN HIGH VOLTAGE SEMICONDUCTOR DEVICES

(71) Applicant: STMicroelectronics International N.V., Geneva (CH)

(72) Inventors: Salvatore Paolo CALABRO', Cernusco Sul Naviglio (IT); Pietro PETRUZZA, Milano, MI (IT); Marta RAIMONDO, Milano (IT)

(73) Assignee: STMicroelectronics International N.V., Geneva (CH)

(21) Appl. No.: 18/519,654

(22) Filed: Nov. 27, 2023

(51) Int. Cl. H01L 29/40

(52) U.S. Cl. CPC H10D 64/01; H10D 64/117

(57) ABSTRACT

A deep trench isolation structure is formed in a semiconductor material body by opening first and second trenches. The sidewalls and bottoms of the first and second trenches are then lined with an insulating material. A halogen-based polymer material is then deposited to cover at least an upper portion of the insulation material in the first trench without covering a portion insulation material at the bottom of the first trench and further cover the insulation material at the sidewalls and bottom of the second trench. An etch process is then used to remove the portion of the insulation material at the bottom of the first trench and the polymer material is removed from both the first trench and second trench. The trenches are then filled with polysilicon to form a substrate plug in the first trench and a field plate electrode in the second trench.

### TECHNICAL FIELD

The present invention relates to a process for manufacturing a deep trench insulation for a high voltage semiconductor device.

### BACKGROUND

For devices manufactured using the Bipolar-CMOS-DMOS (BCD) High-Power technology, the insulation between high voltage devices utilizes Deep Trench Insulation (DTI) technology. This DTI technology ensures the lateral insulation of the high voltage devices from the substrate and enables the devices to occupy a smaller area when compared to other types of electrical isolation. In addition, the DTI technology supports the use of a substrate plug when biasing of the substrate is necessary.

In DTI technology, the semiconductor region where the BCD power device is located is surrounded by an insulating structure formed in a deep annular trench. This trench has insulating walls, typically made of an oxide material, and is filled with conductor, for example made of a polysilicon material. The insulated conductor may have a direct electrical contact with the substrate at bottom of the deep annular trench. This contact ensures electrical connection to the substrate and is referred to in the art as a substrate plug. The insulated conductor may also form a field plate electrode. Conductive regions of the BCD power device are formed in the semiconductor region surrounded by the DTI structure, and are separated therefrom by a distance that can depend on the device operating voltage.

### SUMMARY

In an embodiment, a process for manufacturing a semiconductor device comprises: forming a first trench and a second trench in a semiconductor material body, the first and second trenches extending from an upper surface of the semiconductor material body, the first trench having a first width and first depth, the second trench having a second width and second depth, wherein the first depth is greater than the second depth and wherein the first width is greater than the second width; forming an insulation liner on sidewalls and a bottom of each of the first trench and second trench, the insulation liner defining a residual opening in each of the first trench and second trench; depositing a polymer layer that closes the residual opening in the second trench but does not close the residual opening in the first trench to provide an etch mask with an opening over first trench; etching through the opening in the etch mask formed by the polymer layer to remove the insulation liner at the bottom of the first trench and expose the semiconductor material body; removing the polymer layer from the first trench and second trench; and filling the residual opening in the first trench and second trench with a polysilicon material to form a substrate plug in the first trench that is in contact with the semiconductor material body at the bottom of the first trench and form a field plate electrode in the second trench that is isolated from the semiconductor material body by the insulation liner in the second trench.

In an embodiment, a process comprises: a) forming a first trench and a second trench in a semiconductor material body, the first and second trenches extending from an upper surface of the semiconductor material body, the first trench having a first width, the second trench having a second width, and wherein the first width is greater than the second width; b) forming an insulation material covering sidewalls and a bottom of each of the first trench and second trench; c) depositing a halogen-based polymer material that covers at least an upper portion of the insulation material in the first trench without covering a portion insulation material at the bottom of the first trench and further covers the insulation material at the sidewalls and bottom of the second trench; d) subsequent to step c), removing the portion of the insulation material at the bottom of the first trench; and e) subsequent to step d), removing the halogen-based polymer material from the first trench and second trench.

In an embodiment, a process for manufacturing comprises: forming a first trench in a first region of a first layer of material, the first trench extending from an upper surface of the first layer of material; depositing a polymer layer that partially closes a mouth of the first trench to provide an etch mask with an opening aligned with the first trench; etching through the opening in the etch mask formed by the polymer layer to extend the first trench to a deeper depth; removing the polymer layer; and filling the extended first trench with a conductive material.

In an embodiment, a process for manufacturing a semiconductor device comprises: forming a trench in a semiconductor material body, the trench extending from an upper surface of the semiconductor material body; forming an insulation liner on sidewalls and a bottom of the trench, the insulation liner defining a residual opening in the trench; depositing a polymer layer that only partially closes the residual opening in the trench to provide an etch mask with an opening aligned with the trench; etching through the opening in the etch mask formed by the polymer layer to remove the insulation liner at the bottom of the trench and expose the semiconductor material body; removing the polymer layer from the trench; and filling the residual opening in the trench with a polysilicon material to form a substrate plug in the first trench that is in contact with the semiconductor material body at the bottom of the first trench.

### BRIEF DESCRIPTION OF THE DRAWINGS

For the understanding of the present invention, embodiments thereof are now described, purely as a non-limitative example, with reference to the enclosed drawings, wherein:

FIG. 1 is a cross-sectional view illustrating a portion of a BCD device utilizing two DTI structures;

FIGS. 2A-2J illustrate steps in a process for manufacturing the two DTI structures;

FIGS. 3A-3G illustrate steps in a process for manufacturing; and

FIGS. 4A-4E illustrate steps in a process for manufacturing substrate contacts having a change in tapering.

### DETAILED DESCRIPTION

The following description refers to the arrangement shown in the drawings; consequently, expressions such as “above”, “below”, “upper”, “lower”, “top”, “bottom”, “right”, “left” and the like are relative to the attached Figures and should not be interpreted in a limiting way.

As used herein, the phrase “substantially the same” or “substantially equal” is understood to mean same or equal to within a manufacturing tolerance of the process or to within a margin of +/−10%, preferably less than +/−5%.

The illustrations in the attached Figures are not necessary drawn to scale and certain features have been exaggerated in size, shape, extent, etc., in order to more clearly show the subject matter.

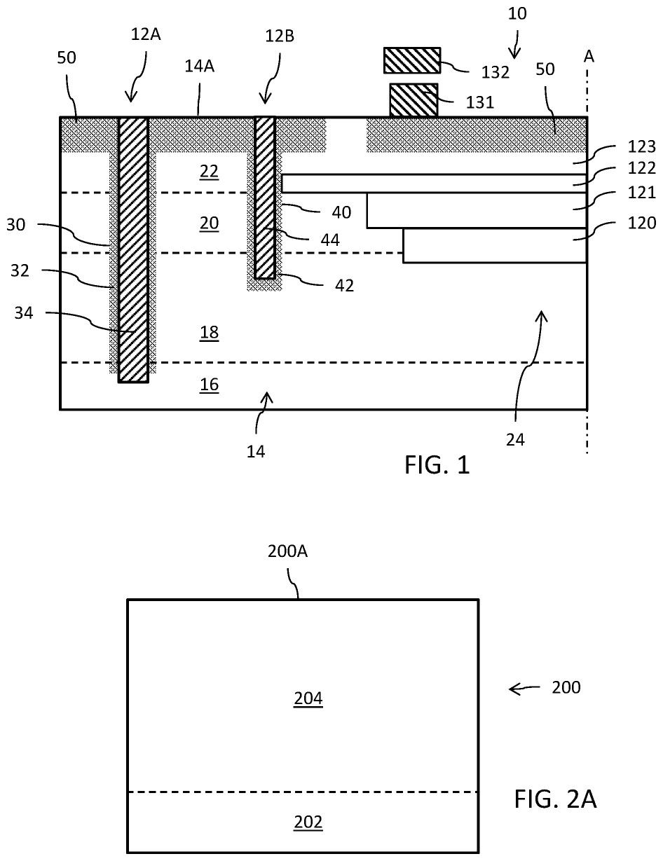

FIG. 1 is a cross-sectional view illustrating a portion of a Bipolar-CMOS-DMOS (BCD) High-Power circuit device 10 utilizing two Deep Trench Insulation (DTI) structures 12A and 12B. FIG. 1 illustrates only half of the device 10; the complete device being obtained by turning FIG. 1 about a central axis A.

A body 14 of semiconductor material, made of silicon for example, has an upper or top surface 14A. The body 14 comprises a heavily p-type doped semiconductor substrate 16, a first p-type doped epitaxial semiconductor layer 18 on and over the substrate 16, a second p-type doped epitaxial semiconductor layer 20 on and over the layer 18, and a third p-type doped epitaxial semiconductor layer 22 on and over the layer 20. The illustration of three epitaxial layers is made by way of example only, it being understood that the body 14 may include fewer or more epitaxial layers as needed for a given device application and configuration.

Each DTI structure 12A and 12B is formed in an annular ring that surrounds a portion 24 of the body 14 which provides the active area of the device 10.

The (outer) DTI structure 12A is formed in a first trench 30 and extends from the surface 14A of the body 14 through the epitaxial layers 22, 20 and 18 until reaching into the substrate 16. The DTI structure 12A includes an insulating layer 32 covering sidewalls of the trench 30 and a conductor 34 filling the insulated trench 30. The insulating layer 32 may be made, for example, of an oxide material, and the conductor 34 may be made, for example, of a p-type doped polysilicon material. The insulating layer 32 is not present at the bottom of the trench 30 and the conductor 34 extends into and is in direct contact with the semiconductor substrate 16. The conductor 34 accordingly forms a substrate plug that can be used, for example, to bias the substrate 16 at a reference, for example ground, voltage level.

The (inner) DTI structure 12B is formed in a second trench 40 and extends from the surface 14A of the body 14 through the epitaxial layers 22 and 20 until reaching into the layer 18 (but without extending further to reach the substrate 16). Thus, the DTI structure 12B does not extend as deeply into the body 14 as the DTI structure 12A. Additionally, the DTI structure 12B has a smaller width than the DTI structure 12A. The DTI structure 12B includes an insulating layer 42 covering sidewalls of the trench 40 and a conductor 44 filling the insulated trench 40. The insulating layer 42 may be made, for example, of an oxide material, and the conductor 44 may be made, for example, of a p-type doped polysilicon material. The conductor 44 is fully insulated from the body 14 by the insulating layer 42 and is configured to form a field plate electrode for the device 10. The insulating material 42 may be made, for example, of an oxide material.

The DTI structure 12B directly surrounds the active area portion 24 of the body 14, while the DTI structure 12A surrounds the DTI structure 12B. The DTI structures 12A and 12B may, for example, be concentric annular structures.

A thick layer 50 of insulating material extends at the surface 14A of the body 14. This insulating material may comprise, for example, an oxide. The layer 50 is shown to have merged with the insulating materials for the layers 32 and 42 at the trenches 30 and 40 for the DTI structures 12A and 12B. One or more openings may be provided in the layer 50 to support contact areas to the active area portion 24.

The active area portion 24 of the body 14 includes a plurality of implanted n-type doped regions 120-123 which extend in the body 14. Region 120 is a deep buried region that extends at an interface between the epitaxial layers 18 and 20. Region 121 is a buried region extending on and in contact with the region 121 in the epitaxial layer 20. Region 122 is an isolation region extending on and in contact with the region 121 at an interface between the epitaxial layers 20 and 22. Region 123 is a well region extending on and in contact with the region 122 in the epitaxial layer 22. For the BCD device 10, well region 123 may be configured to operate at a very high voltage (for example, at more the 70 Volts). The dopant concentration level in each of the implanted regions 120-123 is selected based on the device configuration and operational parameters.

The illustrated sequence and number of implanted regions 120-123, as well as the provision of multiple epitaxial layers 18-22, is an example only showing one of many possible arrangements.

Surface structures 131, 132 extend on and over the surface 14A of the body 14. These surface structures may comprise, for example, a polysilicon layer 131 and a metal layer 132, as well as insulating regions provided therebetween. The surface structures 131, 132 may, for example, form gate regions, electrical lines, capacitor plates, etc. In the case of a transistor configuration, the polysilicon layer 131 may form a transistor gate which would be insulated from the substrate body by a suitable gate oxide layer.

The implanted regions 120-123 and surface structures 131, 132 may, for example, provide various types of electrical components.

In an embodiment, the DTI structure 12B surrounds the implanted regions 120-123 and, in particular, is contiguous to (i.e., in contact with) the peripheral edges of the implanted regions 122 (isolation region) and 123 (well region). Doped p-type regions (not explicitly shown) may be provided in the n-type well region 123 to form, for example, source/drain regions of MOS transistors with the polysilicon layer 131 configured as an insulated transistor gate.

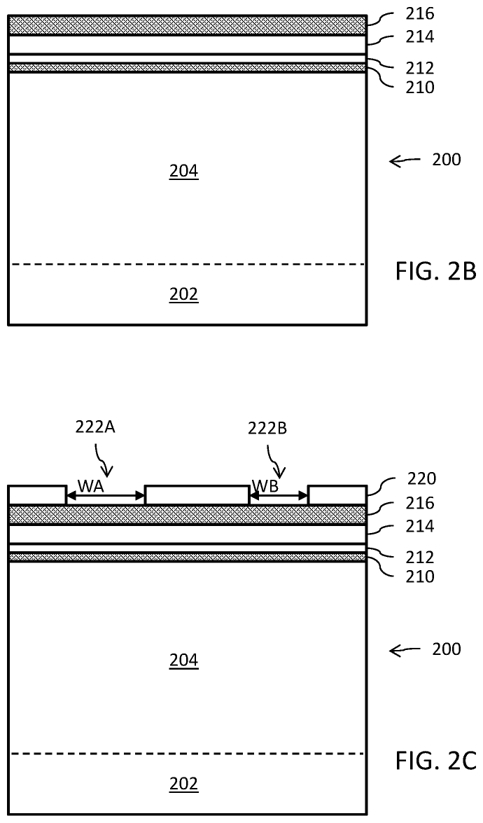

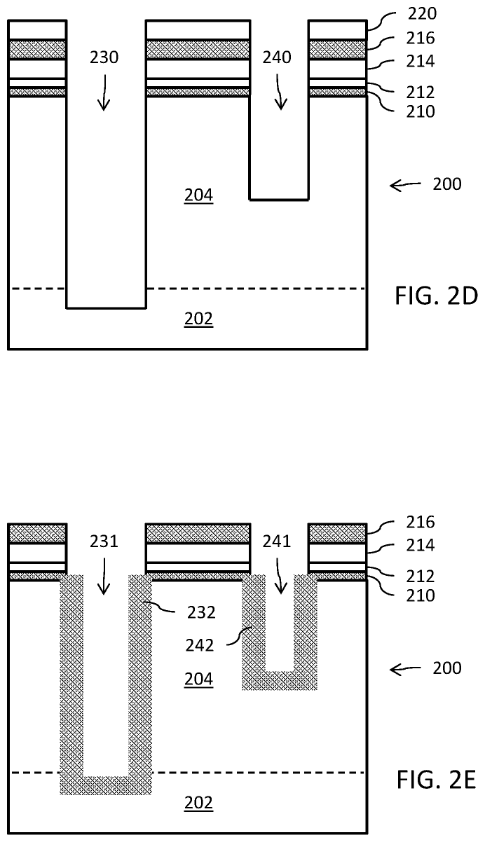

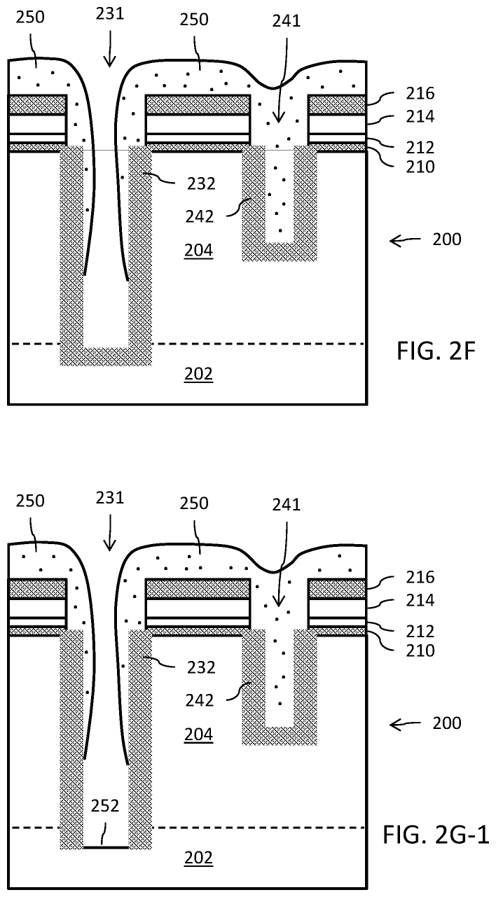

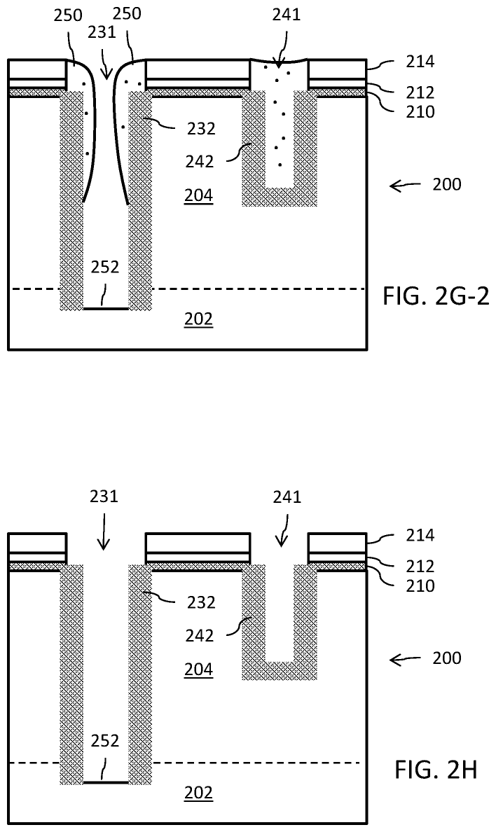

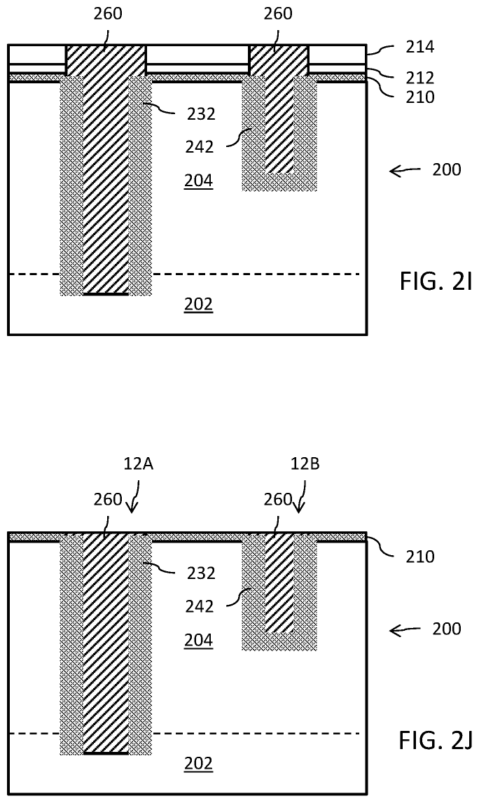

Reference is now made to FIGS. 2A-2J which illustrate steps in a process for manufacturing the DTI structures 12A and 12B.

FIG. 2A—a semiconductor wafer includes a body 200 of semiconductor material having a semiconductor substrate 202 (heavily p-type doped) and one or more overlying epitaxial semiconductor layers 204 (lightly p-type doped).

FIG. 2B—a stack of layers is formed on the upper or top surface 200A of the body 200. This stack includes: a first layer 210 made of an oxide material (thickness of, for example, 50 nm); a second layer 212 made of a nitride material (thickness of, for example, 160 nm); a third layer 214 made of a polysilicon material (thickness of, for example, 700 nm); and a fourth layer 216 made of an oxide (for example, TEOS) material (thickness of, for example, 1200 nm). FIG. 2C—a mask 220 is then formed over the stack with layers 210-216. The mask 220 may, for example, comprise a lithographically patterned resist mask. The mask 220 includes a first aperture 222A and a second aperture 222B spaced apart from each other by a distance of, for example, 6 μm. The first aperture 222A is larger than the second aperture 222B. For example, first aperture 222A may have a width WA while second aperture 222B has a width WB, where WA>WB. In an embodiment, WA=2.1 μm and WB=1.2 μm.

FIG. 2D—the wafer is etched using the mask 220 through the apertures 222A and 222B. Portions of the stack with layers 210-216 and body 200 which are not covered by the mask 220 are removed to form a first trench 230 under the first aperture 222A and a second trench 240 under the second aperture 222B. Due to the larger width WA of the first aperture 222A (relative to the width WB of the second aperture 222B), the width of the first trench 230 is larger than the width of the second trench 240, and the depth of the first trench 230 is deeper than the depth of the second trench 240. In particular, the etching produces the first trench 230 with a depth (for example, of 27 μm) equaling or exceeding the thickness of the one or more overlying epitaxial semiconductor layers 204 so that the first trench 230 reaches at least to the semiconductor substrate 202. The etch forming the second trench 240 proceeds to a shallower depth (for example, 22 μm) that does not reach the semiconductor substrate 202.

The mask 220 is then removed (for example, by stripping).

FIG. 2E—an oxide layer is then grown in each of the first trench 230 and second trench 240. As an example, a thermal oxidation may be performed where the silicon material at the uncovered portions of the body 200 in each trench 230 and 240 is converted to silicon oxide. Oxidation continues until an oxide liner 232 of a desired thickness (for example, equaling or exceeding 550 nm) is present on the sidewalls and bottom of the first trench 230 and an oxide liner 242 of the desired thickness is present on the sidewalls and bottom of the second trench 240. Residual openings 231 and 241 delimited by the liners 232, 242 remain in the trenches 230 and 240, respectively.

In an embodiment, depending on the width WB of the second trench 240, the thermal oxidation may result in the oxide liner 242 completely (or substantially) filling the second trench 240 such that there would be little to no residual opening 241.

In order to obtain the desired substrate plug in the trench 230 and field plate electrode in the trench 240, the challenge at this point is to selectively remove the portion of the oxide liner 232 at the bottom of the trench 230 while maintaining the oxide liner 232 on the sidewalls of the trench 230 and maintaining the oxide liner 242 within the trench 240 on both the sidewalls and bottom.

FIG. 2F—a layer 250 of polymer material is then conformally deposited on the wafer. Due to the difference in width dimensions, and through selection of the thickness of the conformal layer 250, the layer 250 will close the top of the residual opening 241 at trench 240, but will not close the top of the residual opening 231 at trench 230. The layer 250 thus covers at least an upper portion of the oxide liner 232 in the trench 230 without covering the portion of the oxide liner 232 at the bottom of the trench 230. In other words, the layer partially closes a mouth of the trench 230 at the upper surface of the body and fully closes the mouth of the trench 240 at the upper surface of the body. The layer 250 of polymer material forms a protective cap over the trench 240 and simultaneously forms an etch mask structure over the trench 230. The polymer material may, for example, have a chemical composition of N₂CH₃FAr. Thus, the polymer layer 250 deposition process may, for example, utilize a CH₃F precursor in Ar and N₂ atmosphere using a plasma deposition chamber as well as a C₄F₆ precursor in Ar and N₂ atmosphere using the same plasma deposition chamber (without breaking seal). More generally speaking, any suitable halogen-based polymer material could be used for layer 250.

FIG. 2G-1—a dry oxide etch (C₄F₈ with a small quantity of O₂ in a plasma dry etching machine) is then performed using the polymer layer 250 as an etch mask (with the mask opening in layer 250 aligned with the residual opening 231) to remove the portion of the oxide liner 232 at the bottom of the trench 230 and expose surface 252 at the semiconductor substrate 202. This etch is an anisotropic etch (i.e., it acts in a single direction, for example, in the vertical direction).

It will be noted that the polymer deposition and the dry oxide etch can be performed in an integrated process reactor using the same chamber.

FIG. 2H—this dry oxide etching operation will also result in the removal of the polymer layer 250 as well as the removal of the oxide layer 216 in the stack.

It will be noted that, in an embodiment, the etching operation comprises a multistep process: In a first part of the process, an etching is performed to remove the portion of the oxide liner 232 at the bottom of the trench 230 and remove the top part of the polymer layer 250 as well as the oxide layer 216 (leaving a portion of layer 250 within the trench 230). The etching operation utilizes layer 214 as an etch stop. See, FIG. 2G-2. In a second part of the process, for example, using an O₂ plasma stripping, removal of any remaining portions of the polymer layer 250 is completed to obtain the structure shown in FIG. 2H.

It is possible to detect the polymer removal end-point using optical emission spectroscopy (OES). The oxide material at the sidewalls of the trenches 230 and 240 remains in place to define residual openings 231 and 241.

FIG. 2I—next, the residual openings 231 and 241 are filled with a conductor 260. The conductor 260 may, for example, comprise a doped (p-type) polysilicon material. Within the first trench 230, the conductor 260 is in direct contact with the semiconductor substrate 202 at surface 252 to form the substrate plug, but is otherwise insulated from the epitaxial layer(s) 204 by the oxide liner 232. Within the second trench 240, the conductor 260 is fully insulated from the epitaxial layer(s) 204 by the oxide liner 242 to form the field plate electrode.

FIG. 2J—the portion of the conductor 260 above the top surface 200A of the body 200 as well as a portion of the remainder of the layers 210-214 in the stack are then removed. For example, a chemical-mechanical polishing (CMP) operation can be used. This polish can be configured to stop in the nitride layer 212 or at or about the oxide layer 210. As a result, the DTI structures 12A and 12B are formed.

Then, further manufacturing steps may be carried out in a manner known to the person skilled in the art, including forming a thick insulation on the surface of the wafer body 200 (reference 50, FIG. 1) as well forming as electronic components in and above the wafer body 200; and dicing the wafer in order to obtain, for example, the device 10 as shown in FIG. 1.

With the process of FIG. 2A-2J, it is thus possible to manufacture the DTI structures 12A and 12B of FIG. 1 with different geometries in same manufacturing steps.

It will be noted that polymer material from the conformal deposition process in FIG. 2F is deposited at the bottom of the residual opening 241 for trench 240. Notwithstanding removal of the polymer material layer 250 as shown in FIG. 2H, residue of the polymer material may remain at the bottom of trench 240. Specifically, where the polymer material is a Fluorine-based polymer having a chemical composition of N₂CH₃FAr, for example, residual traces of Fluorine (F) and Nitrogen (N) can be detected in the oxide material of the liner 242 at the bottom of the trench 240. Detection of Fluorine (F) and/or Nitrogen (N) would be a telltale sign that the DTI structures of the device were made using the process shown in FIGS. 2A-2J.

More generally speaking, while a Fluorine-based polymer material is one preferred implementation, any halogen-based polymer material could be used. In such a case, the telltale sign that the DTI structures of the device were made using the process shown in FIGS. 2A-2J would be indicated by the presence of residual trace halogen species in the insulating liner 242 at or near the bottom of the second trench 240.

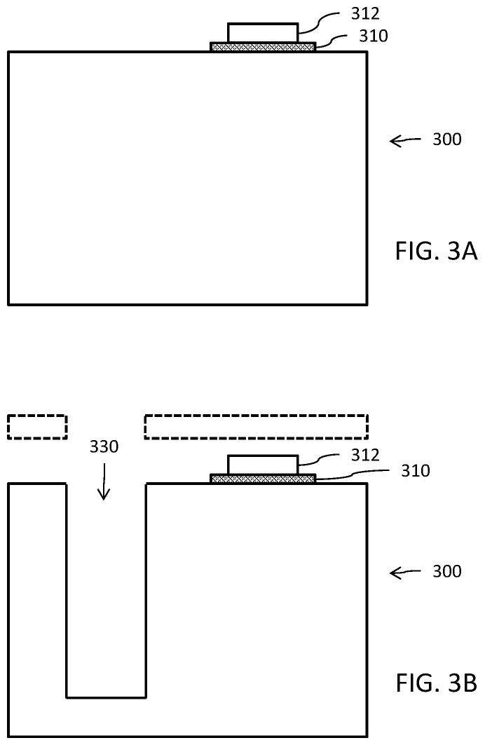

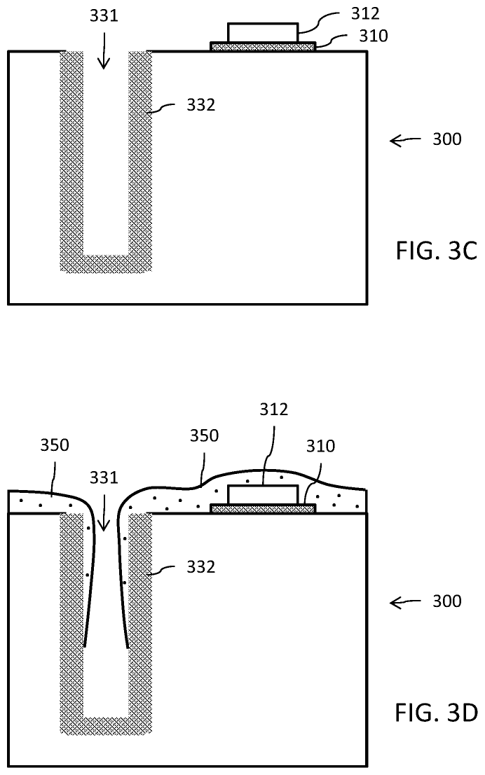

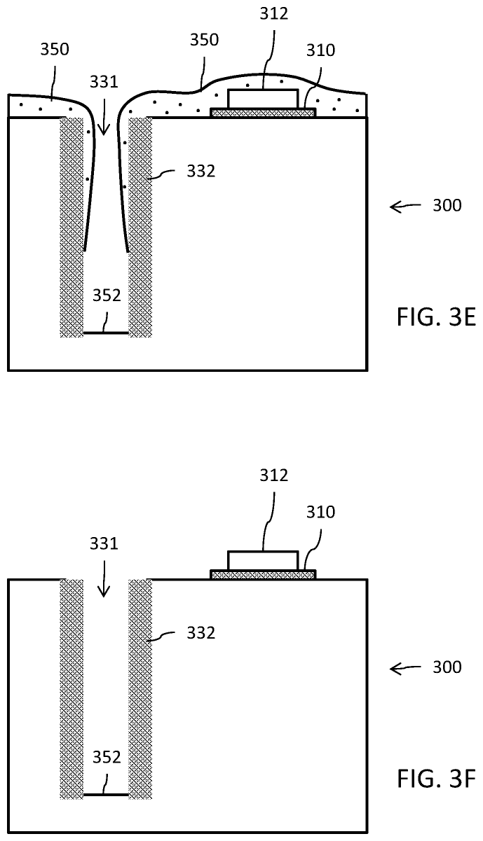

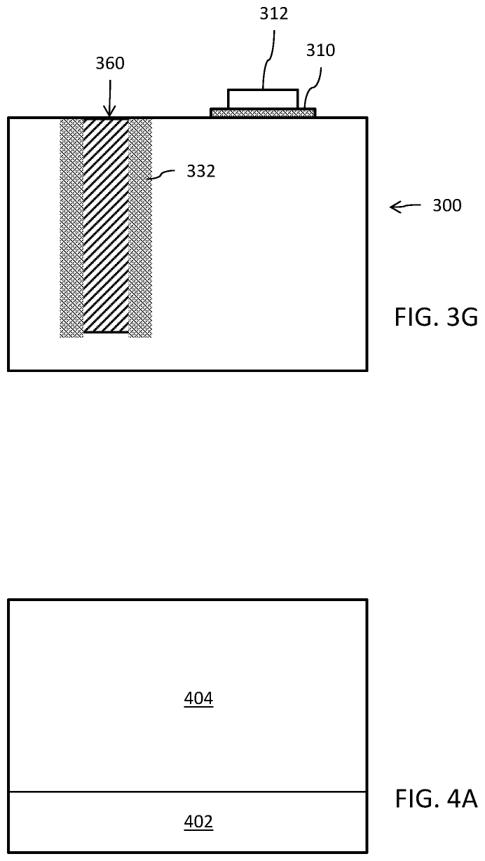

Reference is now made to FIGS. 3A-3G which illustrate steps in a process for manufacturing a substrate plug.

FIG. 3A—a semiconductor wafer includes a body 300 of semiconductor material forming a semiconductor substrate. An integrated circuit is fabricated on and/or in the body 300. This integrated circuit includes an oxide insulating layer 310 and an overlying conductive layer 312. These layers 310 and 312 have been lithographically patterned to desired shapes.

As an example, the integrated circuit could comprise a capacitor where the conductive layer 312 provides a first electrode of the capacitor, the oxide insulating layer 310 provides a capacitor dielectric, and the second electrode of the capacitor is provided by a doped portion at the upper surface of the body 300. The integrated circuit may alternatively comprise a transistor (with layer 312 providing the gate and layer 310 providing the gate oxide) or a resistor (with layer 312 comprising a polysilicon resistance insulated from the substrate by layer 310).

FIG. 3B—the wafer is etched using a mask (schematically shown in dotted lines).

Portions of the body 300 which are not covered by the mask are removed to form a trench 330. The mask 220 is then removed (for example, by stripping).

FIG. 3C—an oxide layer is then grown in the trench 330. As an example, a thermal oxidation may be performed on the silicon material at the uncovered portions of the body 300 in trench 330. Oxidation continues until an oxide liner 332 of a desired thickness is present on the sidewalls and bottom of the trench 330. Residual opening 331 delimited by the liner 332 remains in the trench 330.

In order to obtain a desired substrate plug in the trench 330, the challenge at this point is to selectively remove the portion of the oxide liner 332 at the bottom of the trench 330 while protecting and preserving any other oxide structures, such as the oxide layer 310, that are present in other areas of the wafer.

FIG. 3D—a layer 350 of polymer material is then conformally deposited on the wafer. Through selection of the thickness of the conformal layer 350, the layer 350 will not close the top of the residual opening 331 at trench 330. The layer 350 thus covers at least an upper portion of the oxide liner 332 in the trench 330 without covering the portion of the oxide liner 332 at the bottom of the trench 330. In other words, the layer 350 partially closes a mouth of the trench 330 at the upper surface of the body. The layer 350 of polymer material forms a protective cap over the integrated circuit, in particular the oxide layer 310, present on the surface of the wafer. The polymer material may have the same composition as described noted above.

FIG. 3E—a dry oxide etch (C₄F₈ with a small quantity of O₂ in a plasma dry etching machine) is then performed using the polymer layer 350 as an etch mask (with the mask opening in layer 350 aligned with the residual opening 331) to remove the portion of the oxide liner 332 at the bottom of the trench 330 and expose surface 352 at the semiconductor substrate for the body 300. This etch is an anisotropic etch.

FIG. 3F—this dry oxide etching operation will also result in the removal of the polymer layer 350.

It will be noted that the polymer deposition and the dry oxide etch can be performed in an integrated process reactor using the same chamber. A multistep etch as described above may be used.

FIG. 3G—next, the residual opening 231 is filled with a conductor 360. The conductor 360 may, for example, comprise a doped (p-type) polysilicon material. Within the trench 330, the conductor 360 is in direct contact with the semiconductor substrate at surface 352 to form the substrate plug.

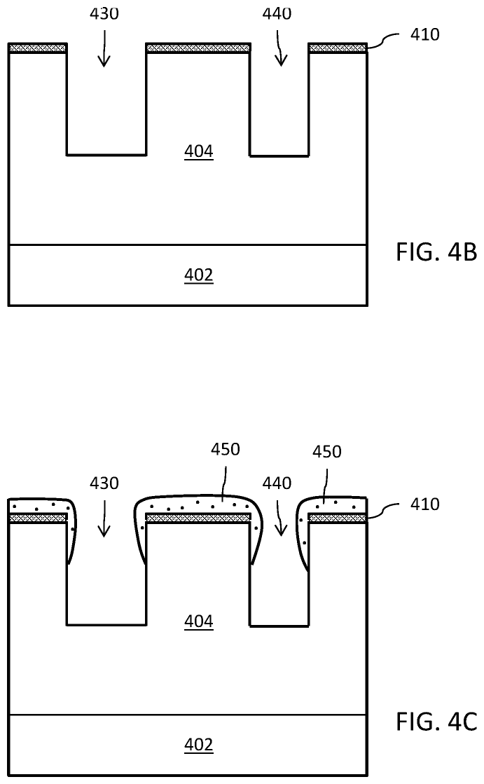

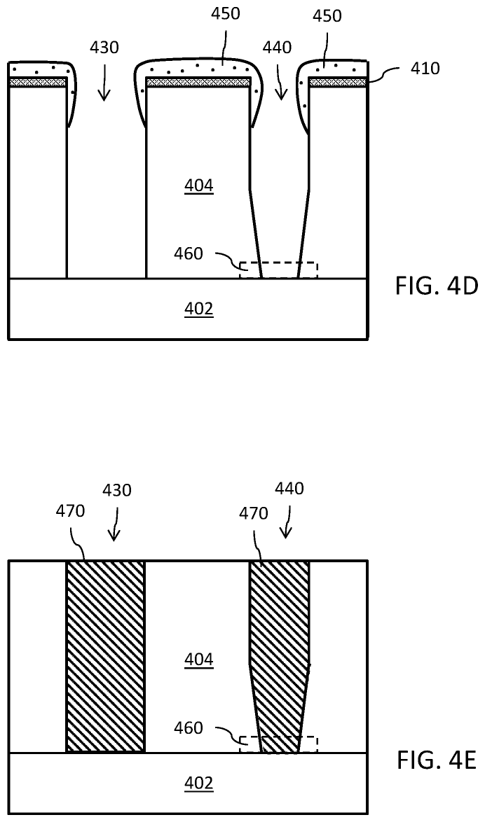

Reference is now made to FIGS. 4A-4E which illustrate steps in a process for manufacturing substrate contacts having a change in tapering.

FIG. 4A—a semiconductor wafer includes a semiconductor substrate 402 and an overlying insulating (for example, oxide) layer 404. The layer 104 may, for example, comprise a pre-metallization dielectric (PMD) layer.

FIG. 4B—the wafer is etched using a mask 410 having mask apertures. The mask 410 may, for example, comprise a lithographically patterned resist mask. Portions of the insulating layer 404 which are not covered by the mask 410 are removed to form a first trench 430 and a second trench 440. In an embodiment, the widths of the first and second trenches are substantially the same. In another embodiment, due to the larger width of the first aperture (relative to the width of the second aperture), the width of the first trench 430 is larger than the width of the second trench 440. In either case, the first and second trenches 430 and 440 have substantially the same first depth, wherein the first depth is less than a thickness of the insulating layer 404.

The mask 410 is then removed (for example, by stripping).

FIG. 4C—at the location of the first trench 430 and the second trench 440, a layer 450 of polymer material is conformally deposited. Through selection of the thickness of the conformal layer 450, the layer 450 will not close the top of either the opening at trench 430 or the opening at trench 440. The layer 450 thus covers at least an upper portion of the sidewall in the trenches 430, 440 without covering the bottom of the trenches 430, 440. In other words, the layer 450 partially closes a mouth of each of the trenches 430, 440 at the upper surface of the layer 404. It will be noted that the opening in polymer layer 450 at trench 430 is wider than then opening in polymer layer 450 at trench 440. The polymer material may have the same composition as described noted above.

FIG. 4D—etching of the wafer then continues using the mask provided by the polymer layer 450. At the first trench 430, with the wider mask opening, the etch extends the first trench (in depth) through the insulating layer 404. This extended depth first trench 430 reaches the upper surface of the layer 402 with the lower portion of the trench 430 having a shape that is substantially identical to the shape at the upper portion of the trench 430. At the second trench 440, with the narrower mask opening, the etch extends the second trench (in depth) through the layer 404. It will be noted, however, that because of the aperture of the polymer layer 450 mask at the second opening 440 is smaller than the aperture of the polymer layer 450 at the first opening 430, the extension of the second trench 440 in a lower portion of the trench 440 will have a tapered shape that is different from the shape at the upper portion of the second trench 440. In other words, the illustrated process is used to make an extended second trench exhibiting a change in tapering. In an embodiment, the second trench will extend completely through the thickness of the insulating layer 404 to reach the substrate 402 (perhaps, for example, exposing a doped region of the substrate 402). Alternatively, the extension of the second trench 440 may be to a depth that is less than the thickness of the insulating layer 404; in such a case perhaps terminating at an integrated circuit structure (for example, a gate electrode) that is present on an upper surface of the substrate 402 (as indicated by the dotted outline structure 460).

The polymer layer 450 is then removed by a suitable etching process. See, for example, the process described above.

FIG. 4E—the extended first and second trenches 430 and 440 are then filled with a conductive material to form an electrical contact 470. The conductive material may comprise, for example, Tungsten (with a suitable barrier liner).

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

1. A process for manufacturing a semiconductor device, comprising:
forming a first trench and a second trench in a semiconductor material body, the first and second trenches extending from an upper surface of the semiconductor material body, the first trench having a first width and first depth, the second trench having a second width and second depth, wherein the first depth is greater than the second depth or wherein the first width is greater than the second width;
forming an insulation liner on sidewalls and a bottom of each of the first trench and second trench, the insulation liner defining a residual opening in each of the first trench and second trench;
depositing a polymer layer that closes the residual opening in the second trench and leaves partially open the residual opening in the first trench to provide an etch mask with an opening over first trench;
etching through the opening in the etch mask formed by the polymer layer to remove the insulation liner at the bottom of the first trench and expose the semiconductor material body;
removing the polymer layer from the first trench and second trench; and
filling the residual openings in the first trench and second trench with a conductive material to form a substrate plug in the first trench that is in contact with the semiconductor material body at the bottom of the first trench and form a field plate electrode in the second trench that is isolated from the semiconductor material body by the insulation liner in the second trench.

2. The process of claim 1, wherein the polymer layer comprises a halogen-based polymer and residual traces of halogen remain at or near the bottom of the second trench following removal of the polymer layer.

3. The process of claim 2, wherein the halogen is Fluorine.

4. The process of claim 1, wherein the first depth is greater than the second depth and the first width is greater than the second width.

5. The process of claim 1, wherein the insulation liner is made of an oxide material.

6. The process of claim 1, wherein the semiconductor material body comprises a semiconductor substrate and at least one epitaxial layer extending on and over the semiconductor substrate, and wherein the exposed semiconductor material body is at or in the semiconductor substrate.

7. The process of claim 1, wherein the semiconductor device is a Bipolar-CMOS-DMOS (BCD) High-Power circuit device.

8. A process for manufacturing a semiconductor device, comprising:
a) forming a first trench and a second trench in a semiconductor material body, the first and second trenches extending from an upper surface of the semiconductor material body, the first trench having a first width, the second trench having a second width, and wherein the first width is greater than the second width;
b) forming an insulation material covering sidewalls and a bottom of each of the first trench and second trench;
c) depositing a halogen-based polymer material that covers at least an upper portion of the insulation material in the first trench and leaves free a portion of the insulation material at the bottom of the first trench and further covers the insulation material at the sidewalls and bottom of the second trench;
d) subsequent to step c), removing the portion of the insulation material at the bottom of the first trench; and
e) subsequent to step d), removing the halogen-based polymer material from the first trench and second trench.

9. The process of claim 8, wherein the halogen is Fluorine.

10. The process of claim 8, wherein residual traces of halogen remain at or near the bottom of the second trench following removal in step e) of the halogen-based polymer material from the first trench and second trench.

11. The process of claim 8, wherein forming the insulation material comprises performing a thermal oxidation operation.

12. The process of claim 8, further comprising, after step e), filling residual openings in the first trench and second trench with a conductive material to form a substrate plug in the first trench that is in contact with the semiconductor material body at the bottom of the first trench and form a field plate electrode in the second trench that is isolated from the semiconductor material body by the insulation material in the second trench.

13. The process of claim 8, wherein the first trench has a first depth, wherein the second trench has a second depth, and wherein the first depth is greater than the second depth.

14. A process for manufacturing, comprising:
forming a first trench in a first region of a first layer of material, the first trench extending from an upper surface of the first layer of material;
depositing a polymer layer that partially closes a mouth of the first trench to provide an etch mask with an opening aligned with the first trench;
etching through the opening in the etch mask formed by the polymer layer to extend the first trench to a deeper depth and form an extended first trench;
removing the polymer layer; and
filling the extended first trench with a conductive material.

15. The process of claim 14, further comprising:
forming in a second region of the first layer of material an element distinct from the trench;
wherein the deposited polymer layer at least partially covers the element.

16. The process of claim 15, wherein said element includes an oxide layer, and wherein said deposited polymer layer completely covers the oxide layer.

17. The process of claim 15, wherein said element is a capacitor including a capacitor dielectric layer, and wherein said deposited polymer layer completely covers the capacitor dielectric layer.

18. The process of claim 14, further comprising:
forming in a second region of the first layer of material a second trench extending from an upper surface of the first layer of material;
wherein said first trench has a first width and said second trench has a second width, where said second width is larger than the first width;
wherein said polymer layer partially closes a mouth of the second trench;
etching to extend the second trench to a deeper depth; and
wherein filling further comprises filling the second trench with the conductive material.

19. The process of claim 18, wherein conductive material filling the extended first and second trenches forms an electrical contact.

20. The process of claim 14, wherein the extended first trench includes an upper portion and a lower portion, and wherein the lower portion has a taper which narrows in width from a width of the upper portion.

21. The process of claim 20, wherein conductive material filling the extended first trench forms an electrical contact.

22. The process of claim 14, wherein the polymer layer comprises a halogen-based polymer.

23. The process of claim 22, wherein the halogen is Fluorine.

24. The process of claim 14, wherein said deeper depth is substantially equal to a thickness of the first layer of material so that the extended first trench reaches a second layer of material under said first layer of material.
